(19) United States
(12) Patent Application Publication
(10) Pub. No.: US 2010/0291475 A1
(43) Pub. Date: Nov. 18, 2010

(54) Silicone Coating Compositions

(76) Inventor: Chenghong Li, Cary, NC (US)

Correspondence Address: SANGYA JAIN;AZ ELECTRONIC MATERIALS USA CORP., 70 MEISTER AVENUE, SOMERVILLE, NJ, 08876, US

(21) Appl. No.: 12/464,170

(22) Filed: May 12, 2009

(51) Int. Cl. G03F 1/00; C08G 77/04; G03F 7/075

(52) U.S. Cl. 430/5; 528/33; 430/270.1

(57) ABSTRACT

The present Invention relates to a novel polymer comprising a unit

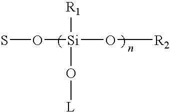

where S is a siloxane chain or an inorganic/organic hybrid chain; L is a thermally labile group; R₁ is alkyl, aryl, alkaryl, —O-L, or 13 O—S; and R₂ is alkyl, aryl, alkaryl, S or L; and n is an integer. The invention also relates to compositions comprising the novel polymer and their use.

### FIELD OF THE INVENTION

The present invention relates to silicone coating compositions and related silicone or inorganic-organic hybrid polymers.

### BACKGROUND

Silicone coating compositions are typically obtained by the sol-gel process through hydrolysis and polycondensation of tetraalkoxysilanes (for example, tetraethoxysilane) and/or alkyltrialkoxysilanes (for example, methyltriethoxysilane). The hydrolysis of alkoxysilanes generates silanols of various types, which then self-condense to form siloxane and water, or condense with alkoxysilane to form siloxane and alcohol. During the sol-gel process, alkoxysilanes and resulting silanols gradually condense, forming polymers with linear, cyclic, cluster, and polycyclic structures, which further condense with either monomeric or polymeric alkoxysilanes/silanols to form polymers of higher molecular weight and/or higher intra molecular linking density, that is more ring structures. When the whole polymer network extends to the whole container (referred to as the gel point), the viscosity shows an increase of several orders of magnitude. For coating applications, the condensation process is controlled to quite far before the gel point. As fluids, silicone coating compositions can be applied to substrates by most coating processes such as dip-coating and spin-coating. After applying on substrates, the coating composition then loses solvent and the silicone polymer undergoes further silanol condensation and eventually becomes heavily crosslinked and forms a dense film. The curing process is often accelerated by heating or the use of acidic or basic catalysts.

Organic-inorganic hybrids are materials consisting of organic polymers or organic species in an inorganic network. A variety of these materials are prepared by sol-gel processing involving bridged or starred alkoxysilanes.

Coatings of silicone or organic-inorganic hybrids have been widely used as top coats for automobile coatings, abrasion resistant coatings for glazing plastics or spectacle lens, or sacrificial or non-sacrificial layers in photolithography for manufacturing of integrated circuits (IC) or micro electromechanical systems (MEMS). In lithography, silicone coatings by either sol-gel processing or chemical vapor deposition (CVD) are used as etch stoppers because of their extremely low etch rate in oxygen plasma. Because of the low cost and spin-coater compatibility compared to CVD, sol-gel derived coatings of silicone or organic-inorganic hybrids are getting popular in semiconductor Industries. Recently, sol-gel derived silicon-containing coatings are developed as anti-reflection hardmasks in multilayer photolithography processes.

While successful in many applications, sol-gel derived coating compositions often have short shelf life because of the continuous condensation of the remaining silanol groups. In other words, these compositions show noticeable aging during storage. The aging related Instability is reflected by gradual changes in molecular weight distribution of polymer, as well as viscosity or other physical properties associated with.

Common approaches to solve the problem include 1) blocking parts of silanol groups with alkoxy groups by carrying out the sol-gel reaction in an alcoholic solvent; 2) adding a monofunctional silane to reduce the average functionality of the silane. However, alkoxy blocking groups are difficult to remove during the latter baking processes because a temperature of 380° C. or higher is required to remove low alkoxy groups. Monofunctional silane, however, will significantly reduce the crosslink density of the system. Because of the additional organic groups, these two methods lead to significant reduction in Si% content, thus not satisfactory for applications requiring extremely high Si content (e.g. anti-reflection hardmasks for trilayer lithography).

The current invention addresses the aforementioned problem.

### SUMMARY OF THE INVENTION

The current invention addresses the aforementioned problem using thermally labile alkoxy groups to stabilize the coating compositions of silicone or inorganic-hybrids. Upon heating, silicone or hybrid organic-inorganic polymers stabilized by these thermally labile groups can be decomposed to form silanol groups and volatile organics, and subsequently condense to form heavily crosslinked systems.

The present invention relates to a polymer comprising a unit

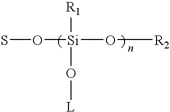

where S is a siloxane chain or an inorganic/organic hybrid chain; L is a thermally labile group; R₁ is alkyl, aryl, alkaryl, —-L, or —O—S; and R₂ is alkyl, aryl, alkaryl, S or L; and n is an integer.

The present invention also relates to a coating composition comprising a polymer comprising a unit

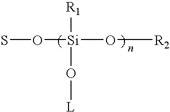

where S is a siloxane chain or an inorganic/organic hybrid chain; L is a thermally labile group; R₁ is alkyl, aryl, alkaryl, —O-L, or —O—S; and R₂ is alkyl, aryl, alkaryl, S or L, and n is an integer; and a solvent.

A method of forming an image on a substrate and a coated substrate using the compositions herein are also part of the invention.

### BRIEF DESCRIPTION OF THE DRAWINGS

FIG. 1 shows examples of polymer structures of the present invention.

### DETAILED DESCRIPTION OF THE INVENTION

The present invention relates to a polymer comprising a unit

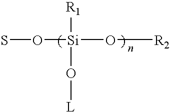

where S is a siloxane chain or an inorganic/organic hybrid chain; L is a thermally labile group; R₁ is alkyl, aryl, alkaryl, —O-L, or —O—S; and R₂ is alkyl, aryl, alkaryl, S or L; and n is an integer.

The present invention also relates to a coating composition comprising a polymer comprising a unit

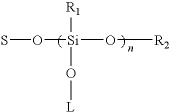

where S is a siloxane chain or an inorganic/organic hybrid chain; L is a thermally labile group; R₁ is alkyl, aryl, alkaryl, —O-L, or —O—S; and R₂ is alkyl, aryl, alkaryl, S or L; and n is an integer; an acid source; and a solvent; further where n relates to the degree of polymerization

A method of forming an image on a substrate and a coated substrate using the compositions herein are also part of the invention.

To address the aforementioned problem, the current invention introduces a moiety Si—O-L comprising thermally labile groups into the polymer to stabilize the polymers of silicone or organic-inorganic hybrids. Upon heating (baking), these thermally labile groups can generate free silanol groups, which then undergo self-condensation to crosslink the system. All thermally labile groups used in chemically amplified photoresists are potential candidates as the group stated in this invention. Examples of the thermally labile -L groups include, for example, t-butyl, t-pentyl (2-methyl-2-butoxy), 1-phenyl-1-ethyl, 2-phenyl-2-propyl, and similar species. L is a thermally labile group and is exemplified by linear, branched or cyclic alkyl, aryl, aralkyl or mixtures of these groups. Essentially, L, is a secondary, preferably tertiary carbon moiety. The tertiary carbon moiety is fully substituted with hydrocarbon groups such as linear, branched or cyclic alkyl, aryl, aralkyl or mixtures of these groups. These silicon-alkoxy species can be thermally cracked to form free silanols and fragments such as butene, propene, styrene, or alpha-styrene. Other thermally labile species such as acetals (or ketals) (represented by Si—O—CRR′—O-L) may also be used, although less preferably. These acetal/ketal species, can be fragmented, in the presence of a strong acid catalyst and moisture, to form free silanol groups, volatile aldehyde (or ketone) and, alcohol species. Large amount of silanol groups formed this way immediately undergo thermal condensation and heavily crosslink the siloxane pre-polymers. The decomposition temperature of the thermally labile group can be dependent of the type of catalyst and its concentration.

The siloxane prepolymers containing these thermally labile alkoxy (OL) groups may be prepared by condensation polymerization of monomers containing these alkoxy groups, for example, di-t-butoxy-di-acetoxysilane, methyl-di-t-butoxysilane, vinyl-di-t-butoxysilane, etc. Many of these silanes can be prepared from corresponding chlorosilanes or acetoxysilanes. Ester exchange of common alkoxysilanes such as methoxysilanes or ethoxysilanes with related alcohols of related labile groups provides another feasible method to make silanes or polymers with thermally labile groups. For example, hydrolysis and polycondensation of related alkoxysilanes in the presence of t-butanol can lead to silicone pre-polymers with t-butoxy groups. Modification of siloxane prepolymers such as hydridosiloxane is another feasible but more expensive approach to introduce those thermally labile groups.

In a coating composition comprising the inventive polymer and an acid source, it is believed that the polymer, upon heating, undergoes deblocking and condensation reactions to form a crosslinked polymer. This can be exemplified by the following chemical reactions using silicone copolymers prepared by co-hydrolysis and co-condensation of di-t-butoxy-diacetoxysilane (90% in molar fraction) and phenyltrimethoxysilane (10% in molar fraction), where x and y are molar percent.

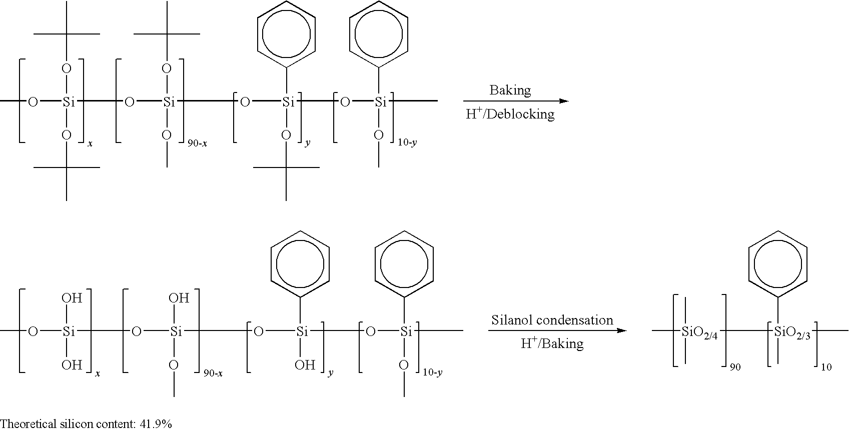

The invention can be any linear, branched, or polycyclic polysiloxanes or polysilsesquioxanes, organic bridged/starred silsesquioxane or siloxane precursors, which contain a least one type of thermally labile groups, which could be cracked thermally or radioactively, in the presence of a catalyst, to generate silanol groups and low molecular weight fragments at relatively low temperature (80-250° C.). Therefore, coating compositions of these polymers can be possibly applied and well cured on organic coatings or plastics with relatively low glass transition temperature (Tg) or decomposition temperature.

Although the aforementioned precursors may still have some silanol groups, they are generally stable at room temperature because of the existence of a large amount of bulky thermally labile groups, and therefore have much longer shelf life than their counterparts derived by normal sol-gel processes.

However, upon heating or irradiation, those thermally labile groups can be catalytically decomposed to generate a large amount of silanol groups, which subsequently crosslink the system. The decomposition of the thermally labile group can be controlled to allow those low molecular weight fragments to be released over a wide temperature range so that a relatively dense film can be obtained. It is also possible to decompose them in a very short time, via irradiation, so that a porous structure is obtained as relatively lower temperature.

Therefore, this is unlike polysiloxanes-/polysilsesquioxanes stabilized with usual alkoxy groups, which thermally decompose at a higher temperature (380-450° C.) and tend to form porous structure with relatively high carbon residue content.

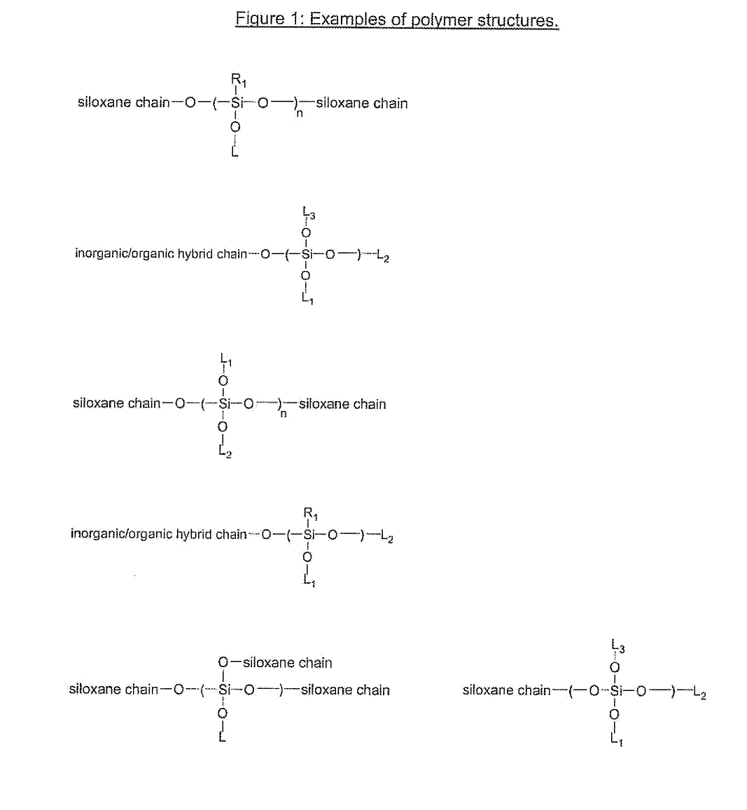

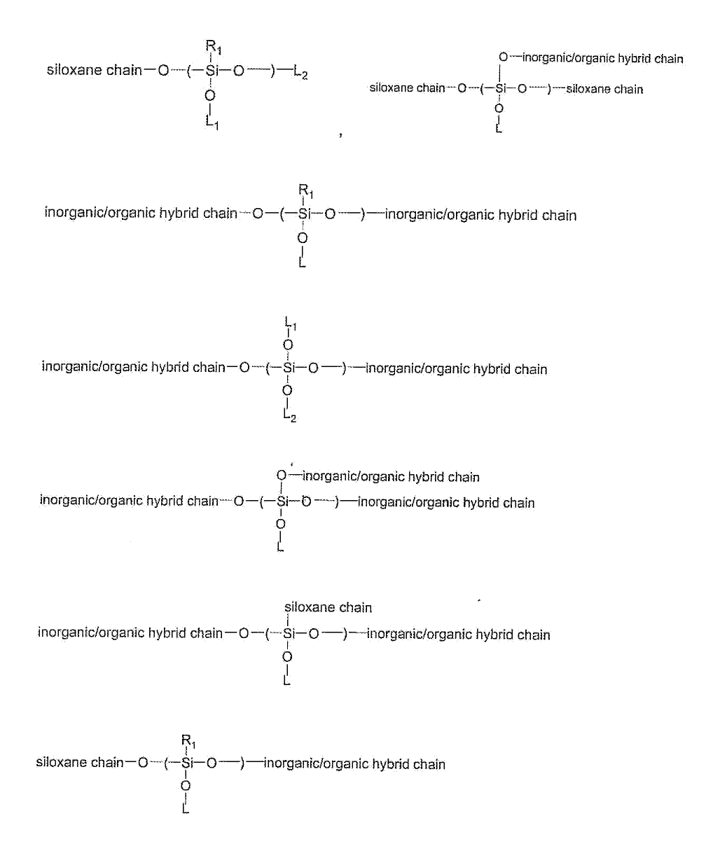

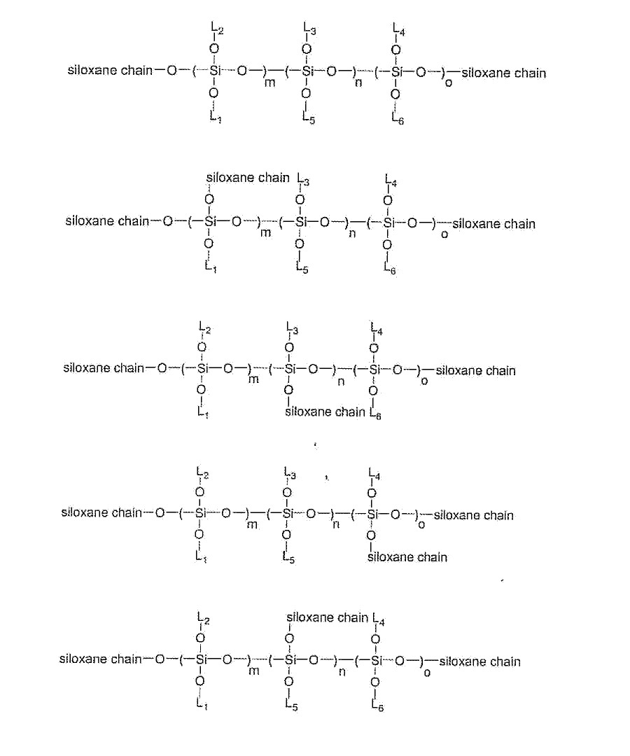

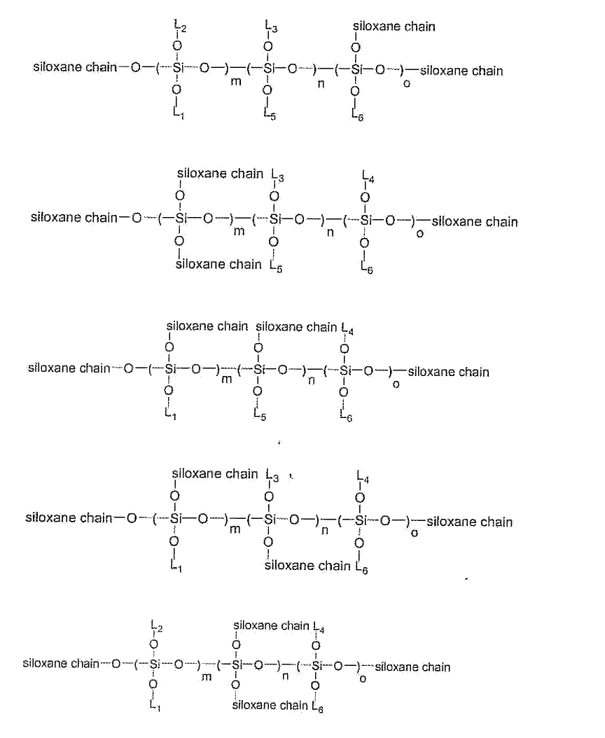

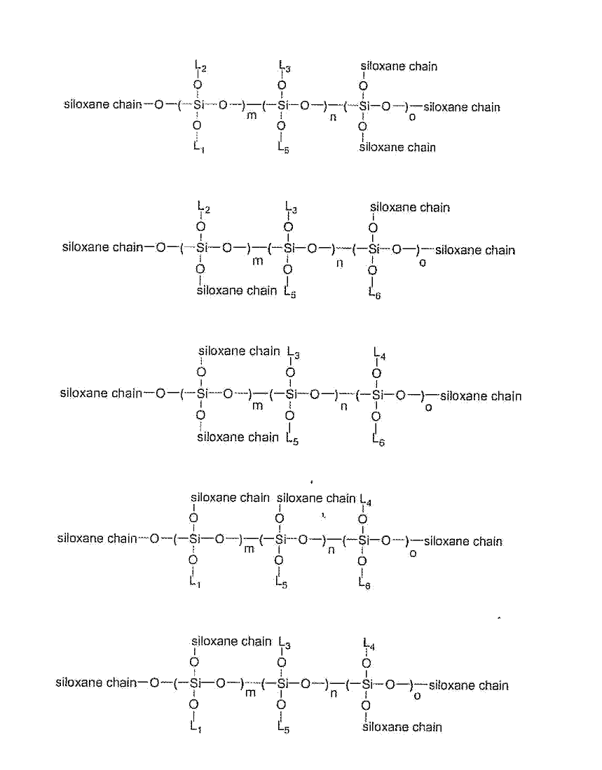

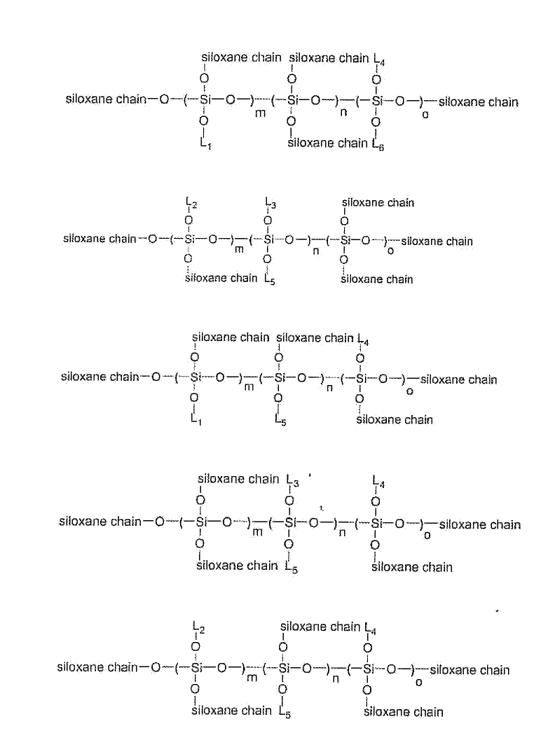

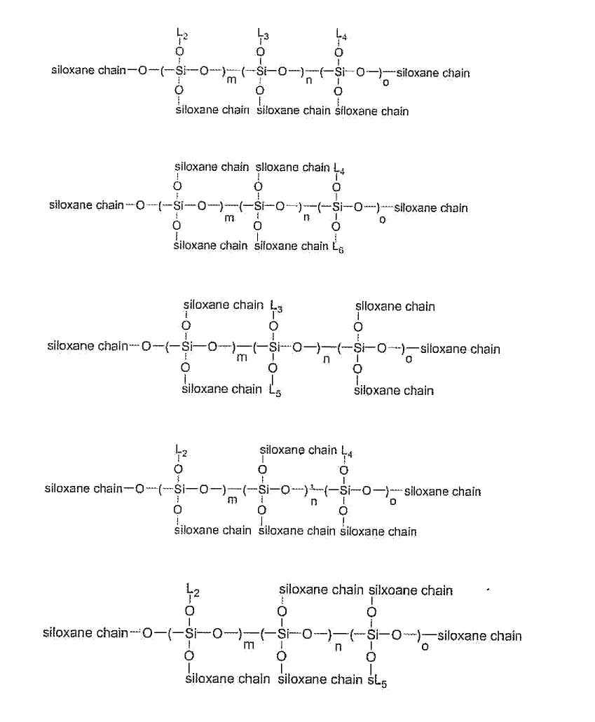

Examples of polymer structures of the present Invention are shown in FIG. 1. L, L₁ to L₆ are different types of leaving groups.

These structures may be prepared by hydrolyzing and polymerizing with one or more types of silanes specified by:

SiRₘXₙ(OL)₄₋ₘ₋ₙ

where
R is an alkyl or aryl group
X is a better leaving group than —OL group (examples of X are halogen, substituted carboxylate, methoxy or ethoxy group, etc),
L is a thermally labile group,
m and n are integers 0 to 3, and m+n≦3.

Non-limiting examples including
Si(t-BuO)₂(OAc)₂
Si(t-BuO)₃(OH)
Si(t-BuO)₂(OCH₃)₂
Si(t-BuO)₂Cl₂
Si(CH₃)(t-BuO)(OAc)₂
SICH═CH₂(t-BuO)(OAc)₂ etc.

Such silanes can be easily converted from the related acetoxysilane or silane halides by partially reacting with t-butanol. For example,
Si(CH₃)(t-BuO)(OAc)₂ from CH₃Si(OAc)₃
Si(CH═CH₂)(t-BuO)(OAc)₂ from CH₂═CHSi(OAc)₃

These materials may be prepared by co-hydrolyzing and co-condensing with one or more of silanes with thermally labile groups specified above using common methoxysilanes, ethoxysilanes, or silanols, if stable in isolated state. Examples of these alkoxysilanes are:
Si(OCH₃)₄
Si(CH₃)(OCH₃)₃
Si(C₆H₅)(OCH₃)₃
(C₂H₅O)₃SiC₆H₄Si(OC₂H₅)₃
(HO)(CH₃)₂SiC₆H₄Si(CH₃)₂(OH)

Alkyl refers to both straight and branched chain saturated hydrocarbon groups having 1 to 20 carbon atoms, for example, methyl, ethyl, propyl, isopropyl, tertiary butyl, dodecyl, and the like. Examples of the linear or branched alkylene group can have from 1 to 20 carbon atoms and include such as, for example, methylene, ethylene, propylene and octylene groups. Alkyl also refers to nonaromatic cyclic structures, such as cyclohexane, adamantine, norbornane, etc.

Aryl refers to an unsaturated aromatic carbocyclic group of from 6 to 20 carbon atoms having a single ring or multiple condensed (fused) rings and include, but are not limited to, for example, phenyl, tolyl, dimethylphenyl, 2,4,6-trimethylphenyl, naphthyl, anthryl and 9,10-dimethoxyanthryl groups.

Aralkyl refers to an alkyl group containing an aryl group. It is a hydrocarbon group having both aromatic and aliphatic structures, that is, a hydrocarbon group in which an alkyl hydrogen atom is substituted by an aryl group, for example, tolyl, benzyl, phenethyl and naphthylmethyl groups.

Alkylene refers to a straight, branched or cyclic multivalent aliphatic hydrocarbon group, preferably having from 1 to about 20 carbon atoms. There may be optionally inserted along the alkylene group one or more oxygen, sulfur or substituted or unsubstituted nitrogen atoms. Exemplary alkylene groups include methylene, ethylene, propylene, cyclohexylene, methylenedioxy and ethylenedioxy.

Alkenylene refers to a straight, branched or cyclic multivalent aliphatic hydrocarbon group, preferably having from 2 to about 20 carbon atoms and at least one double bond. There may be optionally inserted along the alkenylene group one or more oxygen, sulfur or substituted or unsubstituted nitrogen atoms. Exemplary alkenylene groups include —CH═CH—CH═CH— and —CH═CH—CH₂.

Alkynylene refers to a straight, branched or cyclic multivalent aliphatic hydrocarbon group, preferably having from 2 to about 20 carbon atoms and at least one triple bond. There may be optionally inserted along the alkynylene group one or more oxygen, sulphur or substituted or unsubstituted nitrogen atoms. Exemplary alkyhylene groups include —C≡C—C≡C, —C≡C— and —C≡C—CH₂—.

Arylene refers to a monocyclic or polycyclic multlivalent aromatic group, preferably having from 5 to about 20 carbon atoms and at least one aromatic ring. There may be optionally inserted around the arylene group one or more oxygen, sulfur or substituted or unsubstituted nitrogen atoms. Exemplary arylene groups include 1,2-, 1,3- and 1,4-phenylene.

Aralkylene refers to moieties containing both alkylene and aryl species, typically containing less than about 24 carbon atoms in the alkylene portion and 1 to 5 aromatic rings in the aryl portion, and typically aryl-substituted alkylene.

Alternatively, siloxane/silsesquioxane/silicate with thermally labile groups may be prepared by sol-gel reaction of typical alkoxy silanes. After the molecular weight increases to the required level, multifunctional acetoxysilane such as methyltriacetoxysilane or tetraacetoxysilane is added to block the reactive silanol sites. Then the alcohol of the related thermal labile group is added to react with the remaining silicon acetoxy groups and convert them to thermal labile groups.

Ester exchange may provide the easiest method to prepare siloxane/silsesquioxane/silicate with thermally labile groups. In this approach, alkoxysilanes are hydrolyzed and condensed in the alcohol of the related thermal labile group in the presence of a strong acid catalyst or an ester exchange catalyst. A significant amount of thermal labile groups can be introduced by ester exchange.

The present inorganic/organic hybrid polymers may be prepared through hydrolysis and condensation of bridged or starred organosilane mixture specified by

RₘXₙ(OL)₃₋ₘ₋ₙSi—R′—SiR_{m′}X_{n′}(OL)_{3-m′-n′}

where
R is an alkyl or aryl group
X is a better leaving group than —OL group, where X may be halogen, substituted carboxylate, methoxy or ethyoxy group,
L is a thermally labile group,
R′ is an organic diradical containing 0-25 carbon, oxygen, nitrogen, or other atoms,
m, n, m′, n′ are each integers 0 to 3, and m+n≦3, m′+n′≦3.

In some instances, it is preferable that (n+n′)/2 Is between 1.8 and 2.2 so that the system does not gel during the reaction.

Examples of R′ include

1) direct bond, i.e. a disilane

2) —(CH₂)ₙ—

3) —C≡C— (acetylene)

4) —CH═CH— (ethylene)

5) —C₆H₄— (benzene)

6) —C₆H₄—O—C₆H₄—

7) —C₆H₁₀— (cyclohexyl)

8) —CH₂CH₂C₆H₄C₂H₂—

or star structure with k arms specified by

R″-[SiRₘXₙ(OL)₃₋ₘ₋ₙ]ₖ

where R, X, L, m, and n are defined above and k is the number of arms on the star structure (3 to 6)
m, n are integers (0-3), and m+n=0-3

Examples of R″ include

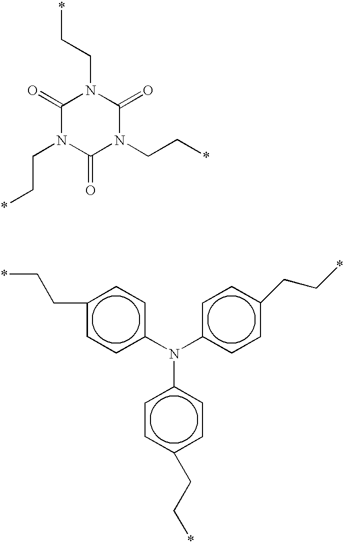

where * indicates the site where a silyl group is attached.

These bridged or starred organosilanes may be used as mixtures, but the average number of X group should be close to 2 (1.8-2.2) so that polymerization before triggering off the OL group does not lead to a gel.

These materials can be easily prepared from related chlorosilane, methoxysilane, or ethoxysilane compounds that are converted to the above structures by either ester exchange or alcoholysis.

The degree of polymerization (n, m, o, p) for the polymer represents the number of repeating units in the polymer chain and is dependent on the molecular weight of the polymer. The weight average molecular weight can range from 3,000 to about 100,000 and the degree of polymerization can be easily determined from the weight average molecular weight. Values for m, n, o, and p can range from about 1 to about 200.

The acid catalyst used with the present invention can be one or several nonvolatile moderately strong acids such as p-toluenesulfonic acid, dodecylbenzensulfonic acid, etc. Sulfuric acid, triflic acid or other super acids may be used but are less preferred because of potential side reactions related to polymer, additives, or solvents, which may affect the shelf life or performance of the composition.

Thermal acid generators and photoacid generators are generally preferred over free acid catalysts because of fewer side reactions. Generally, the preferred thermal acid generators are those which decompose between 80 and 200° C. to generate nonvolatile moderately strong, or strong acid, or even super acid. Examples of thermal acid generators are nitrobenzyl tosylates, such as 2-nitrobenzyl tosylate, 2,4-dinitrobenzyl tosylate, 2,6-dinitrobenzyl tosylate, 4-nitrobenzyl tosylate; benzenesulfonates such as 2-trifluoromethyl-6-nitrobenzyl 4-chlorobenzenesulfonate, 2-trifluoromethyl-6-nitrobenzyl 4-nitrobenzenesulfonate; phenolic sulfonate esters such as phenyl-4methoxybenzenesulfonate; alkyl ammonium salts of organic acids, such as triethylammonium salt of 10-camphorsulfonic acid, and the like, iodonium salts like di-tert-butylphenyliodonium bis(trifluoromethanesulfonyl) nitride, etc., p-toluenesulfonic acid, and the like.

Examples of photoacid generators include are onium salts, sulfonate compounds, nitrobenzyl esters, triazines, etc. The preferred photoacid generators are onium salts and sulfonate esters of hydoxyimides, specifically diphenyl iodonium salts, triphenyl sulfonium salts, dialkyl iodonium salts, triakylsulfonium salts, and mixtures thereof.

A combination of thermal acid generator and photoacid generator may also be used. While a crosslinker may be used, but if not silane based, it is less preferred because the crosslinking in the current invention is predominately executed by generation of silanol groups and subsequent silanol condensation. Many siloxane/silsesquioxane coating compositions are crosslinked with salts of strong base with weak acid, for example, tetramethylammonium acetate, potassium acetate, etc. In photolithography, the catalyst from these coatings tends to interfere with the chemically amplified photoresists directly applied over it, causing footing or scumming problems. Silicone coatings described in the present invention involves only acidic catalyst, the possibility of incompatibility with photoresists may be reduced. In one embodiment the novel composition may be free of base catalyst, especially a base or its salt.

The coating layer after heat and/or radiation treatment becomes insoluble in organic solvents. Generally, siloxane polymers, even highly crosslinked, are susceptible to strong bases. Solubility in solutions of strong bases such as sodium hydroxide, potassium hydroxide, or tetramethylammonium hydroxide varies depending on the composition of the coatings. With proper composition, the dissolution rate of many silicpne coatings in typical aqueous alkaline developer is low enough for lithographic applications.

While many solvents may be used in the present invention, alcohols other than those of thermally labile groups are not preferred because of concerns about the possible ester exchange which removes the thermally labile groups.

Examples of solvents for the coating composition include esters, glymes, ethers, glycol ether esters, ketones, lactones, cyclic ketones, and mixtures thereof. Examples of such solvents include, but are not limited to, amyl acetate, isobutyl isobutyrate, pentyl propionate, propylene glycol methyl ether acetate, cyclohexanone, 2-heptanone, ethyl 3-ethoxy-propionate, ethyl lactate, gamma valerolactone, methyl 3-methoxypropionate, and mixtures thereof. The solvent is typically present in an amount of from about 40 to about 99 weight percent. In certain instances, for example in lithography, the addition of lactone solvents is useful in helping flow characteristics of the antireflective coating composition when used in layered systems. When present, the lactone solvent comprises about 1 to about 10% of the solvent system. y-valeroiactone is a useful lactone solvent.

The: composition of the present invention can be coated on the substrate using techniques well known to those skilled in the art, such as dipping, spin-coating or spraying. Depending upon the desired applications, the film thickness of the silicone or organic-hybrid coating ranges from about 0.01 μm to about 5 μm. The coating can be heated for a time between 30 seconds to several hours on a hot plate or convection oven or other well known heating methods to remove any residual solvent and induce crosslinking if desired. In photolithography, the solids level of anti- reflective compositions is typically less than 15% and generally about 1 to about 10%. For antireflective coatings, the film thickness is typically in the range of 0.01 μm to about 0.50 μm. With thin films, it is possible that a 30 to 120 second bake could be enough to insolubilize the coating to prevent intermixing with the photoresist.

Silicone coating compositions described in the current invention may be used in a wide range of Industries (for example, the vamish, printing ink, paint, and photolithography markets). One example of use is in the photolithography industry as an antireflection hard mask (silicon bottom antireflective coating) There are two types of photoresist compositions, negative-working and positive-working. When negative-working photoresist compositions are exposed image-wise to radiation, the areas of the resist composition exposed to the radiation become less soluble to a developer solution (e.g. a cross-linking reaction occurs) while the unexposed areas of the photoresist coating remain relatively soluble to such a solution. Thus, treatment of an exposed negative-working resist with a developer causes removal of the non-exposed areas of the photoresist coating and the creation of a negative image in the coating, thereby uncovering a desired portion of the underlying substrate surface on which the photoresist composition was deposited.

On the other hand, when positive-working photoresist compositions are exposed image-wise to radiation, those areas of the photoresist composition exposed to the radiation become more soluble to the developer solution (e.g. a rearrangement reaction occurs) while those areas not exposed remain relatively insoluble to the developer solution. Thus, treatment of an exposed positive-working photoresist with the developer causes removal of the exposed areas of the coating and the creation of a positive image in the photoresist coating. Again, a desired portion of the underlying surface is uncovered.

Negative working photoresist and positive working photoresist compositions and their use are well known to those skilled in the art.

A process of the instant invention comprises coating a substrate with a composition of the present invention and heating the substrate on a hotplate or convection oven or other well known heating methods at a sufficient temperature for sufficient length of time to remove the coating solvent, and crosslink the polymer, to a sufficient extent so that the coating is not soluble in the coating solution of a photoresist or in a aqueous alkaline developer. An edge bead remover may be applied to clean the edges of the substrate using processes well known in the art. The heating ranges in temperature from about 70° C. to about 500° C. If the temperature is below 70° C. then insufficient loss of solvent or insufficient amount of crosslinking may take place. A film of a photoresist composition is then coated on top of the coating of the present invention and baked to substantially remove the photoresist solvent. The photoresist is image-wise exposed and developed in an aqueous developer to remove the treated resist. An optional heating step can be incorporated into the process prior to development and after exposure. The process of coating and imaging photoresists is well known to those skilled in the art and is optimized for the specific type of resist used. The patterned substrate can then be dry etched in a suitable etch chamber to remove the exposed portions of the anti-reflective film, with the remaining photoresist acting as an etch mask.

The substrate can be Si, SiO₂, SION, SiN, p-Si, a-Si, SiGe, W, W—Si, Al, Cu, Al—Si, low-k dielectrics, and the like. As the semiconductor feature size shrink, actinic wavelengths gradually decreases, and the numerical aperture (NA) of the lithography tools gradually increases, especially with the advent of immersion lithography, In order to increase the resolution of optical systems. A trilayer process is one process which addresses the requirements of the shrinking resist thickness with shorter wavelength and higher NA lithography tools and the problem of lower reactive ion resistance of ArF excimer 193 nm photoresists. A typical trilayer lithographic process involves three layers of materials on semiconductor substrates. On top of the substrate mentioned above is an approximately 40 -300 nm thick underlayer of high carbon content organic material, over the carbon layer is a typically 20-150 nm thick silicon-containing anti-reflection hard mask (Si-BARC) layer, for which the silicone coating compositions of the present invention can be used, and on top of the hardmask is typically a 70-200 nm thick top layer of photoresist. By this process, the resist was exposed and developed to form resist patterns on the anti-reflection hard mask, then Si-BARC layer is opened using fluorine plasma chemistry (e.g. CF₄) so that resist pattern is transferred to the Si-BARC. In general, Si-BARC/hard mask has similar or slightly faster etch rate than the resist, so resist patterns, although thin, can be easily transferred to the Si-BARC layer. Then Si-BARC/hard mask's excellent etch resistance to oxygen plasma is used to open the thick high C % organic layer to obtain high aspect ratio patterns of organic layer, which can be used to pattern the substrates to obtain deep trenches or holes. With current resists alone, it is simply unlikely to obtain features with such a high aspect ratio because the resist is not a good mask anymore. Trilayer systems are well known to those skilled in the art.

Unless otherwise indicated, all numbers expressing quantities of ingredients, properties such as molecular weight, reaction conditions, and so forth used in the specification and claims are to be understood as being modified in all instances by the term “about.” Each of the documents referred to above are Incorporated herein by reference in its entirety, for all purposes. The following specific examples will provide detailed illustrations of the methods of producing and utilizing compositions of the present invention. These examples are not intended, however, to limit or restrict the scope of the invention in any way and should not be construed as providing conditions, parameters or values which must be utilized exclusively in order to practice the present invention.

### EXAMPLE 1

### Poly(t-butoxysiloxane 90-co-phenylsilsesquloxane 10)

In a 1 liter one-neck round bottom flask were added 7.0 g of phenyltrimethoxysilane and 128 g of t-butanol. Then 19.0 g of 0.1N HCl aqueous solution were added to hydrolyze the phenyltrimethoxysilane. After the mixture had been stirred for 30 minutes, 92.99 g of di-butoxy-diacetoxysilane, plus 231 g of t-butanol were added, causing an exotherm. After the exotherm, the mixture was refluxed for 48 hrs at ° C., Then, 280 g of propylene glycol methyl ether acetate (PGMEA) were added. Low boiling point solvents or byproducts were removed by evaporation. The final solution obtained had a solids level of 9.77%. Molecular weight by GPC (Mn=7801, Mw=34586). Solvents remaining in the composition by GC (PGMEA, 89.38%, Acetic acid 6.77%, and t-butanol 3.37%). ¹H-NMR showed that about 51% of the silicon atoms in the polymer had a t-butoxy group attached thereto. GPC studies showed that there was little change in molecular weight after standing at room temperature for 2 months, indicating that the polymer was stable.

### EXAMPLE 2

### Poly(methyl-t-butoxysiloxane 90-co-phenylsisilsesquioxane 10)

In a 1 liter one-neck round bottom flask were added 102.2 9 of methyltriacetoxysilane and 34.4 9 of t-butanol and heated at 80° C. for 4 hrs. The resulting acetic acid was removed by vacuum distillation. ¹H-NMR showed the mixture consisted of 15.3% of methyltriacetoxysilane, 71.6% of methyl-t-butoxy-diacetoxysilane, and 13.2% of methyl-di-butoxy-acetoxysilane.

In a 100 ml Erlenmeyer flask were added 150 g of PGMEA and 10.22 g of phenyltrimethoxysilane and stirred until a homogenous solution was formed. Then, 10.72 g of 0.1N HCl aqueous solution were added to the solution. The solution in the flask was stirred for 30 minutes.

The solution in the Erienmeyer flask was then poured into the solution in the I liter one-neck flask. The mixture was heated at 80° C. for 4-6 hrs and then the low boiling point byproducts were removed by vacuum distillation. A clear solution with a solids level of 24.8% was obtained. Molecular weight by GPC (Mn=3180, Mw=11932). Solvent compositions remaining in the composition by GC (PGMEA, 88.10%, acetic acid, 10.24, t-butanol, 1.65%)

### EXAMPLE 3

### Poly(t-butoxysiloxane-co-1,4-bis(oxydimethylsilyl)benzene)

In a 1 liter one-neck round bottom flask were added 2.20 g of 1,4-bis(hydroxydimethylsilyl)benzene and 40.0 g of tetrahydrofuran (THF). After the bis(hydroxydimethylsilyl)benzene was dissolved, 22.8 g of di-t-butoxydiacetoxysilane and 78 g of PGMEA were added and the mixture was heated to reflux temperature for 4 hrs and then cooled to room temperature overnight. The solution was filtered to remove insoluble materials from the starting bis(hydroxydimethylsilyl)benzene. THF was then removed by vacuum distillation. The final solution had a solids level of 11.07%. GC results of the composition were: PGMEA, 91.51%, acetic acid, 3.71%, THF 2.82%, t-butanol, 1.96%.

### EXAMPLE 4

### Poly(t-butoxysiloxane-co-1,4-bis(trioxysilyl)benzene)

In a 1 liter one-neck round bottom flask were added 50 g of t-butanol, 3.0 g of 1,4-bis(triethoxysilyl)benzene, and 22.0 g of di-t-butoxydiacetoxysilane. 2.91 g of 0.1N HCl aqueous solution was then added. The mixture was heated to reflux temperature for 4 hrs and then 50.0 g of PGMEA was added. Most of the solvent was removed by vacuum distillation, leaving a waxy material. The waxy material was re-dissolved in 50 g of PGMEA and a clear solution with a solids level of 14.24% was obtained.

### EXAMPLE 5

### Poly(t-butoxysiloxane(60)-co-methylsiloxane(30)-co-phenylsilsesquioxane(10))

In a 1 liter one-neck round bottom flask were added 2.14 9 of methyldimethoxysilane, 3.61 g of phenyltrimethoxysilane, and 25 g of THF. 2.60 g of 0.1N HCl aqueous solution was then added to the solution and stirred for 30 minutes. Then, 19.25 g of di-t-butoxydiacetoxysilane was added to the mixture and the mixture was then heated to reflux temperature for 6 hrs. 50.0 g of PGMEA was then added to the mixture and mixture was vacuum distilled to remove solvent, leaving a waxy material. The waxy material was re-dissolved in 50 g of PGMEA and a clear solution with a solids level of 14.24% was obtained.

### EXAMPLE 6

### Poly(t-butoxysiloxane(70)-co-methylsilsesquioxane(30)-co-Phenylsilsesquioxane(10))

In a 1 liter one-neck round bottom flask were added 7.81 g of methyltrimethoxysilane, 4.84 g of phenyltrimethoxysilane, and 50.0 g of THF. 7.46 g of 0.1N HCl aqueous solution was then added to the solution and stirred for 30 minutes. Then, 56.21 g of di-t-butoxydiacetoxysilane was added to the mixture and the mixture was then heated to reflux temperature for 6 hrs. 100.0 g of PGMEA was then added to the mixture and mixture was vacuum distilled to remove solvent, leaving a waxy material. The waxy material was re-dissolved in 100 g of PGMEA and a clear solution with a solids level of 27.74% was obtained Example 7-8 demonstrate the deblocking mechanism for the t-butoxy functional siloxane polymers

### EXAMPLE 7

In a 25 ml vial were added 10 g of the polymer solution from Example 1 and 10 mg of p-toluenesulfonic acid monohydrate (p-TSA, 98.5% from Aldrich Chemical). After the p-TSA dissolved, the solution was filtered using a 0.2 micron pore size PTFE filter (Sample 7A). Clean wafers (4″ in diameter) were used as substrates for FTIR spectrum acquisition. After background acquisition, a silicon wafer (Wafer 7A) was coated with Sample 7A using a spin-coater at a spin-rate of 1000 rpm for 60 seconds and air-dried for 1 minute. The coated wafer was then baked on a hotplate at 200° C. for 2 minutes. After background correction, the FTIR spectrum was collected for Wafer 7A coated with Sample 7A. FTIR spectra were acquired for Wafer 7A before and after the baking process. As a control, FTIR spectra were similarly collected for a polymer solution of Example 1 without p-TSA (Sample 7B). FTIR absorption at 2950 cm⁻¹ showed that without p-TSA, no obvious decomposition had occurred during the baking process, while with p-TSA catalyst, the disappearance of 2950 cm⁻¹ absorption peak means almost all t-butoxy groups had decomposed.

### EXAMPLE 8

In a 25 ml vial were added 10 ml of polymer solution of Example 1 (about 1.0 g in solids) and 10 mg of p-TSA (Aldrich). The solution was dried in vacuum at 55° C. (Sample 8A). As a control, 10 ml of polymer solution from Example 1 without any catalyst was placed In a 25 ml vial and also vacuum dried (Sample 8B). Thermogravimetric analysis (TGA) was conducted for both samples using a temperature profile of isotherm at 40° C. for 2 minutes, followed by ramping at 50° C./min to 230° C. and an isotherm of 5 minutes, and then a ramp of 50° C./min to 800° C. and an isotherm of 10 min. TGA data indicate that for Sample 8B (no p-TSA), the t-butoxy group thermally decomposed at about 380° C., causing a significant weight loss. However, in Sample 8A (with p-TSA), the t-butoxy group decomposed gradually at lower temperature.

### EXAMPLE 9

Polymers 1-6 from Examples 1 to 6 respectively were made into coating compositions for trilayer ArF excimer UV photolithographic applications with the components as shown in Table 1. All compositions were prepared based on an acid catalyst level of about 1% by solids. The compositions were mixed to form homogenous solutions and then filtered using 0.2 micron PTFE disk filters. The coatings were prepared on 6″ wafers by spin-casting an aliquot of composition on the wafer using a spin rate of 1500 rpm for 60 seconds and then baked at 230° C. for 60 seconds. Film thickness, contact angle, and optical constants [refractive index (n) and absorption coefficient (k)] were measured for these coatings and listed in Table 1.

TABLE 1
Coating examples and their properties

| | Component | | | | | | |
|---|---|---|---|---|---|---|---|
| Component | Solids | #9-1 | #9-2 | #9-3 | #9-4 | #9-5 | #9-6 |
| Polymer 1 | 9.77% | 10.0 | 8.0 | | | | |
| Polymer 2 | 24.8% | | 2.0 | | | | |
| Polymer 3 | 11.1% | | | 9.0 | | | |
| Polymer 4 | 14.2% | | | | 7.0 | | |
| Polymer 5 | 14.2% | | | | | 6.0 | |
| Polymer 6 | 27.7% | | | | | | 6.0 |
| p-TSA | 2.5% | | | | | 0.4 | 0.2 |
| TAG1 | 2.5% | | | | | 0.4 | 0.2 |
| DBSA | 10% | 0.098 | | 0.12 | 0.12 | | |
| PGMEA | | 40 | 50 | | | | |
| IBIB | | | | 57 | 57 | 40 | 43 |
| H₂0 contact | | 74-76 | 87-89 | 73-74 | 36-37 | 70-76 | 66-70 |
| angle ° | | | | | | | |
| FT (Å) | | 396.3 | 295 | 228.0 | 267.1 | 458.4 | 447.1 |
| Std FT (Å) | | 4.9 | 2.6 | 3.0 | 2.4 | 4.2 | 3.2 |
| n @ 193 nm | | 1.5996 | 1.5365 | 1.3806 | 1.464 | 1.6184 | 1.6102 |
| k @ 193 nm | | 0.2063 | 0.2062 | 0.2658 | 0.2503 | 0.1963 | 0.1868 |
| Si % (TGA) | | 37.5-38 | 36.5-37.5 | 36.6-37.5 | 37-38 | 38-39.5 | 36.6-37.5 |

Acronyms in the table
p-TSA: p-toluene sulfonic acid
TAG1: di-(4-t-butylphenyl)iodonium bis(trifluoromethanesulfonyl)nitride
DBSA: dodecylbenzene sulfonic acid
PGMEA: propylene glycol methyl ether acetate
IBIB: isobutyl isobutyrate
FT: film thickness, angstrom

### EXAMPLE 10

This example demonstrates the imaging part of a typical trilayer process using t-butoxy functional siloxane polymer precursors as the anti-reflection hard mask.

In this example, the trilayer process was conducted on ACT12 system. AZ® U10F Underlayer (available from AZ Electronic Materials USA Corp.) was spin-cast on several 8″ silicon wafers, baked at 230° C. for 60s, to form a coating layer having a thickness of 200 nm. A silicon anti-reflection hard mask layer, selected respectively from #9-1, #9-2, #9-5 and 9-6 in Table 1, was coated individually over the underlayer coating coated over the substrate and then baked at 230° C. for 60s to form a coating thickness of 380 nm. AZ® 2110P Photoresist (193 nm), available from AZ Electronic Materials USA Corp, was coated on top of the silicon anti-reflection hard mask coating layer to form a 150 nm thick film, which was soft-baked at 100° C. for 60s. Exposure was conducted on a Nikon 3060 system, using ID11 Y dipole illumination, reticle 3182 with 6% phase shift, and a numerical aperture (NA) of 0.85. The photoresist was then post exposure baked (PEB) at 110° C. for 60 s, and developed using AZ® 300 MIF developer for 30 seconds. When a coating containing the polymer from Example 1 is fully deblocked and cured by heating In the presence of a strong acid catalyst, the resulting SiO₂ like amorphous layer is still very rich in Si-OH content. Although it contains phenyl groups, this SiO₂-like layer is not compatible with some photoresists. When the photoresist was developed, the resist pattern often loses adhesion to this Si-BARC layer and collapses. This problem is generally solved by surface treatment with hexamethyidisilazane (HMDS); however, this involves an additional step. In the present invention, it was found that methylsilsesquioxane or methylsiloxane modified resins, either in form of blends or copolymers, could significantly improve the adhesion of the resist patterns to the silicon bottom antireflective coating. #9-1 showed 80 nm line (1:1 pitch) resist patterns on Si-BARC/hard mask at a defocus of 0.1 micron at different energy doses. Because of poor resist compatibility, resist lines failed to obtain sufficient adhesion to the #9-1 film. It was found that increasing the acid level or acid strength only decreases resist compatibility.

Reasonable resist patterns were obtained from compositions #9-2, #9-5, and #9-6 in Table 1, due to incorporation of methylsilsesquioxane or methylsiloxane units. However, blending may be more effective since methylsilsesquioxane homopolymer has a very low surface energy and tends to migrate to surface before fully cured. #9-2 has a minor component of phenylsilsesquioxane, but it is very close to a methylsilsesquioxane homopolymer. The low surface energy of the coating #9-2 is reflected by the highest contact angle with water from Table 1.

Incorporation of methylsiloxane component is an approach to improve cure efficiency and increase Si%; however, this method is limited by the corresponding sacrifice in developer solubility of the coating. With 27% of methylsiloxane (molar fraction based on Si), reasonable resist patterns can be obtained for 80 nm features.

I claim:

1. A polymer comprising a unit 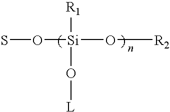
where S is a siloxane chain or an inorganic/organic hybrid chain;
L is a thermally labile group;
R₁ is alkyl, aryl, alkaryl, —O-L, or —O—S;
R₂ is alkyl, aryl, alkaryl, S or L; and
n is degree of polymerization.

2. The polymer of claim 1 which comprises a unit selected from 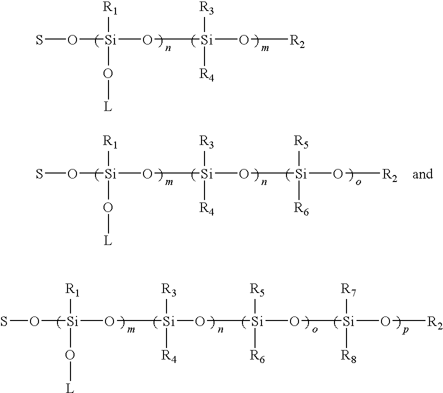
where R₃, R₄, R₅, R₆, R₇, and R₈ are each individually R₁ and n, m, o and p are each degree of polymerization.

3. The polymer of claim 1 wherein the inorganic/organic hybrid chain are siloxane and/or silsesquioxane and/or silicate chains or networks including organic segments which bridge two silicon atoms through Si—C bonds.

4. The polymer of claim 1 which is selected from the group consisting of poly(t-butoxysiloxane-co-phenylsilsesquioxane), poly(methyl-t-butoxysiloxane-co-phenylsilsesquioxane), poly(t-butoxysiloxane-co-1,4-bis(oxydimethylsilyl)benzene), poly(t-butoxysiloxane-co-1,4-bis(trioxysilyl)benzene), poly(t-butoxysiloxane-co-methylsiloxane-co-phenylsilsesquioxane), and poly(t-butoxysiloxane-co-methylsilsesquioxane-co-phenylsilsesquioxane).

5. The polymer of claim 1 wherein the Inorganic/organic hybrid chain has a repeating unit 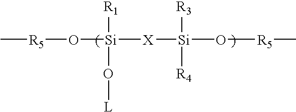
where X is a direct bond or a linking group which is not O; and R₅ is alkyl, aryl, or alkaryl.

6. The polymer of claim 5 where X is a direct bond.

7. The polymer of claim 5 where X is a linking group.

8. The polymer of claim 5 where the linking group is selected from multivalent straight, branched or cyclic unsubstituted or substituted alkylene, multivalent straight, branched or cyclic unsubstituted or substituted alkenylene, multivalent straight, branched or cyclic unsubstituted or substituted alkynylene, multivalent unsubstituted or substituted arylene, multivalent unsubstituted or substituted aralkylene, multivalent unsubstituted or substituted alkylene-aryl-alkylene, or multivalent aryl-X1-aryl, where the alkylene, alkenylene, alkynylene, arylene, aryl, and aralkylene can optionally contain one or more oxygen, nitrogen, or sulfur atoms, and X1 is a linking group.

9. A coating composition comprising the polymer of claim 1; an acid source; and a solvent.

10. The coating composition of claim 9 wherein the polymer comprises a unit 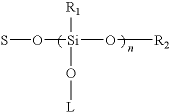
where S is a siloxane chain or an inorganic/organic hybrid chain;
L is a thermally labile group;
R₁ is alkyl, aryl, alkaryl, —O-L, or —O—S; and
R₂ is alkyl, aryl, alkaryl, S or L, and n is degree of polymerization.

11. The coating composition of claim 9 wherein the polymer comprises a unit 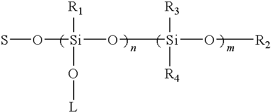
where R₃ and R₄ are each individually R₁.

12. The coating composition of claim 9 wherein the polymer is selected from the group consisting of poly(t-butoxysiloxane-co-phenylsilsesquioxane, poly(methyl-t-butoxysiloxane-co- phenylsilsesquioxane, poly(t-butoxysiloxane-co-1,4-bis(oxydimethylsilyl)benzene), poly(t-butoxysiloxane-co-1,4-bis(trioxysilyl)benzene), poly(t-butoxysiloxane-co-methylsiloxane-co-phenylsilsesquioxane), and poly(t-butoxysiloxane-co-methylsilsesquioxane-co-phenylsilsesquioxane).

13. The coating composition of claim 9 wherein for the polymer, the inorganic/organic hybrid chain has a repeating unit 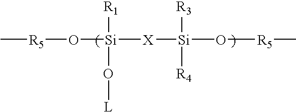
where X is a direct bond or a linking group which is not O; and R₅ is alkyl, aryl, or alkaryl.

14. The coating composition of 9, where the composition is free of base and/or its salt.

15. A method of forming an image on a substrate comprising, a) coating the substrate with the composition of claim 9; b) heating the coating of step a); c) forming a coating from a photoresist solution on the coating of step b); d) heating the photoresist coating to substantially remove solvent from the coating; e) image-wise exposing the photoresist coating; f) developing an Image using an aqueous alkaline developer; g) optionally, heating the substrate prior to and after development; and h) dry etching the composition of step b).

16. The method of claim 15 wherein the substrate Is a carbon-layer/hardmask.

17. The method of claim 15 wherein the substrate is selected from Si, SiO₂, SiON, SiN, p-Si, a-Si, W, W—Si, Al, Cu, and Al—Si.

18. A coated substrate comprising: a substrate having thereon; a layer of the composition of claim 9; and a layer of a positive photoresist composition above the composition.

19. The coated substrate of claim 18 wherein the substrate is a carbon-layer/hardmask.
